(19) United States
(12) Patent Application Publication
(10) Pub. No.: US 2025/0317141 A1
(43) Pub. Date: Oct. 9, 2025

(54) SWITCHING DRIVERS

(71) Applicant: Cirrus Logic International Semiconductor Ltd., Edinburgh (GB)

(72) Inventors: Eric J. KING, Austin, TX (US); Hasnain AKRAM, Austin, TX (US); John L. MELANSON, Austin, TX (US)

(73) Assignee: Cirrus Logic International Semiconductor Ltd., Edinburgh (GB)

(21) Appl. No.: 19/050,750

(22) Filed: Feb. 11, 2025

Related U.S. Application Data
(63) Continuation-in-part of application No. 18/626,995, filed on Apr. 4, 2024.

(51) Int. Cl. H03K 17/687; H03H 7/01; H04R 3/04

(52) U.S. Cl. CPC H03K 17/6871; H04R 3/04; H03H 7/0115

(57) ABSTRACT

This application relates to methods and apparatus for switched mode drivers. A BTL driver has a switch network operable in different switch states, wherein, in each switch state, each of first and second output nodes is connected to a respective one of a first switching voltage, a second switching voltage or an intermediate switching voltage between the first and second switching voltages which is provided by a driver capacitance. A controller is configured to control the switch network to operate in a sequence of switch states to generate a differential drive signal based on an input signal. The controller is configured such that operation of driver switch network in said sequence of switch states to generate said differential drive signal provides voltage regulation of the intermediate voltage provided by said driver capacitance.

The field of representative embodiments of this disclosure relates to methods, apparatus and/or implementations concerning or relating to switching driver circuits, and in particular to switching driver or amplifier circuits as may be used to drive a transducer, such as an audio transducer.

Many electronic devices include transducer driver circuitry for driving a transducer with a drive signal, for instance for driving an audio output transducer of the device or a connected accessory, with an audio drive signal.

In some applications, the transducer driver circuitry may include a switching driver, e.g. a class-D amplifier or the like, for generating the drive signal. Switching drivers, sometimes referred to as switched-mode drivers or switched-mode amplifiers, can be relatively power efficient and thus can be advantageously used in some applications. A switching driver generally operates to switch an output node between different switching voltages, with a duty cycle that provides a desired drive signal voltage, on average over the course of one or more switching cycles.

Multi-level switching drivers, also referred to as multi-level converters, have been proposed which modulate the output node(s) of the switching driver between selected ones of a set of at least three different switching voltages. For instance, rather than just modulate an output node between high and low switching voltages, say VDD and ground, the relevant output node could be modulated with a controlled duty-cycle between an intermediate voltage, such as VDD/2 for example, and a selected one of the high and low switching voltages depending on the desired output voltage. Switching between VDD and VDD/2, or between VDD/2 and ground, reduces the magnitude of the modulation in voltage at the output node, with benefits of reduced ripple current and EMI emissions. In some cases, capacitors may be used as part of the switching driver, e.g. as flying capacitors, to provide at least one of the switching voltages. One example is a multi-level switching driver arrangement based on a known flying capacitor multi-level inverter topology.

Known multi-level flying capacitor switching drivers typically require relatively complex control arrangements for monitoring the voltages of the flying capacitors and adjusting the switching sequence in response to maintain charge balance and hence maintain the correct voltage on the flying capacitors.

Embodiments of the present disclosure relate to methods and apparatus for switching drivers that at least mitigate at least some of the above-mentioned issues.

According to an aspect of the disclosure there is provided a switching driver circuit for driving a load comprising: first and second output nodes for outputting a differential drive signal for driving the load; a driver switch network operable in a plurality of different switch states, wherein, in each switch state, each of the first and second output nodes is connected to a respective one of at least a first switching voltage, a second switching voltage and an intermediate switching voltage, wherein the intermediate switching voltage is a voltage between the first and second switching voltages and is provided by a driver capacitance that can be selectively connected to each of the first and second output nodes, and a controller configured to control the driver switch network to operate in a sequence of said switch states to generate said differential drive signal based on an input signal; wherein the controller is configured such that operation of driver switch network in said sequence of switch states to generate said differential drive signal provides voltage regulation of the intermediate voltage provided by said driver capacitance.

In some implementations, operation in the switch states may result in a load current to the load and the controller may be configured such that, for at least some values of differential drive signal, the sequence of switch states includes at least one instance of a switch state in which the driver capacitance is charged by the load current and at least one instance of a switch state in which the driver capacitance is discharged by the load current. A differential output voltage between the first and second output nodes may be the same in the switch state in which the driver capacitance is charged by the load current as in the switch state in which the driver capacitance is discharged by the load current. The controller may be configured such that the load current that flows during the at least one instance of the switch state in which the driver capacitance is charged by the load current substantially matches the load current that flows during the at least one instance of the switch state in which the driver capacitance is discharged by the load current. The controller may be configured such that a total duration in the switching cycle of the at least one instance of the switch state in which the driver capacitance is charged by the load current is the same as the total duration in the switching cycle of the at least one instance of the switch state in which the driver capacitance is discharged by the load current.

The first voltage may be a first supply voltage and the second voltage may be a second supply voltage. The first supply voltage may have a value V, the second supply voltage may be ground and the intermediate voltage may have a value equal to V/2. In such a case, the switch state in which the driver capacitance is charged by the load current may comprise a switch state in which one of the first and second output nodes is connected to the first supply voltage V and the other of the first and second output nodes is connected to the driver capacitance at the intermediate voltage V/2; and the switch state in which the driver capacitance is discharged by the load current may comprise a switch state in which said one of the first and second output nodes is connected to the driver capacitance at the intermediate voltage V/2 and said other of the first and second output nodes is connected to the second voltage at ground.

In some implementations, the driver capacitance may comprise a driver capacitor connected, in use, between first and second capacitor nodes, wherein the first capacitor node can be selectively connected to each of the first and second output nodes and the second capacitor node is connected to a defined reference voltage. The defined reference voltage may be one of the first and second voltages. The defined reference voltage may be ground. In some implementations, the driver capacitor may be the only capacitor to which the first and second output nodes may be connected.

In some implementations, the driver switch network may comprise, for each of the first and second output nodes: a first set of three switches for selectively connecting a first common node to the first switching voltage, to the intermediate switching voltage and to the relevant output node respectively; and a first set of three switches for selectively connecting a second common node to the second switching voltage, to the intermediate switching voltage and to the relevant output node respectively; wherein the controller is configured such that in a switch state where an output node is connected to the intermediate switching voltage, the relevant switches of both the first and second sets of three switches are controlled to be on.

In some implementations, the switching driver circuit may further comprise: a bias switch network configured to selectively connect nodes of the driver switch network to the intermediate voltage so as to bias said nodes of the driver switch network to the intermediate voltage to manage a voltage stress across switches of the driver switch network when in an off state, wherein the controller is configured to control the bias switch network based on the switch state of the driver switch network. The bias switch network may be configured such that substantially no current flows via the bias switch network in any of the switch states.

In another aspect there is provided a multi-channel amplifier system comprising a plurality of switching driver circuits according to any of the embodiments described herein, wherein a common capacitance connected to a common capacitance node is configured as the driver capacitance for each of switching driver circuits. The multi-channel amplifier system may be configured such that a first switching driver circuit of the plurality is configured to operate in a switch state in which the load current in the first switching driver circuit is supplied to the common capacitance node at the same time as a second switching driver circuit of the plurality is configured to operate in a switch state in which the load current in the second switching driver circuit is supplied to the common capacitance node.

In another aspect there is provided a multi-level switching driver circuit for driving a load connected between first and second output nodes with a differential drive signal, the multi-level switching driver circuit comprising: first and second supply nodes for receiving first and second supply voltages; first and second capacitor nodes for connection, in use, to a driver capacitor; a network of switches configured to selectively connect each of the first and second output nodes to a respective one of the first supply node, the second supply node or the first capacitor node; and a controller for controlling the network of switches in a sequence of switch states to generate said differential drive signal, wherein operation of driver switch network in said sequence of switch states to generate said differential drive signal provides charge balancing of the driver capacitor.

In some implementations, the second capacitor node may be connected to a defined reference voltage.

In another aspect there is provided a multi-level switching driver circuit for driving a load in a bridge-tied-load configuration comprising: first and second output nodes for connection, in use, to the load; first and second capacitor nodes for connection, in use, to a driver capacitor, wherein the first capacitor node can be selectively connected to each of the first and second output nodes by a switch network and the second capacitor node is connected to a defined reference voltage; and a controller configured to control the multi-level switching driver circuit to generate a differential driving signal across the load based on an input signal, wherein the controller is configured, for at least some values of differential driving signal to operate in a switching cycle of states that includes: a first state in which the first capacitor node is connected to one of the first and second output nodes and is charged by a current flowing via that one of the first and second output nodes; and a second state in which the first capacitor node is connected to the other of the first and second output nodes and is discharged by a current flowing via that other one of the first and second output nodes.

In another aspect there is provided a multi-channel amplifier system comprising: a plurality of switching drivers, each of the switching drivers being configured to selectively modulate a voltage at at least one output node of the switching driver between selected switching voltages to drive a respective load; wherein one of said switching voltages is a capacitor voltage that is, in use, provided by a common driver capacitance which is common to each of the plurality of switching drivers and which is connected to a common capacitor node; and a controller for controlling operation of the plurality of switching drivers in a switching cycle such that load currents flowing to or from the common capacitor node from or to each of the plurality of switching drivers provides voltage regulation of the capacitor voltage.

It should be noted that, unless expressly indicated to the contrary herein or otherwise clearly incompatible, then any feature described herein may be implemented in combination with any one or more other described features.

For a better understanding of examples of the present disclosure, and to show more clearly how the examples may be carried into effect, reference will now be made, by way of example only, to the following drawings in which:

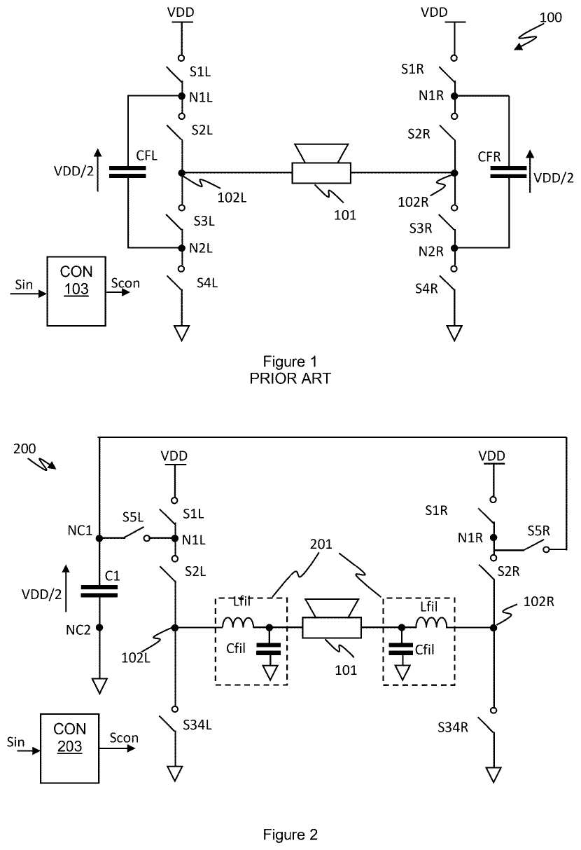

FIG. 1 illustrates one example of a known multi-level flying capacitor switching driver;

FIG. 2 illustrates an example of a multi-level switching driver according to an embodiment;

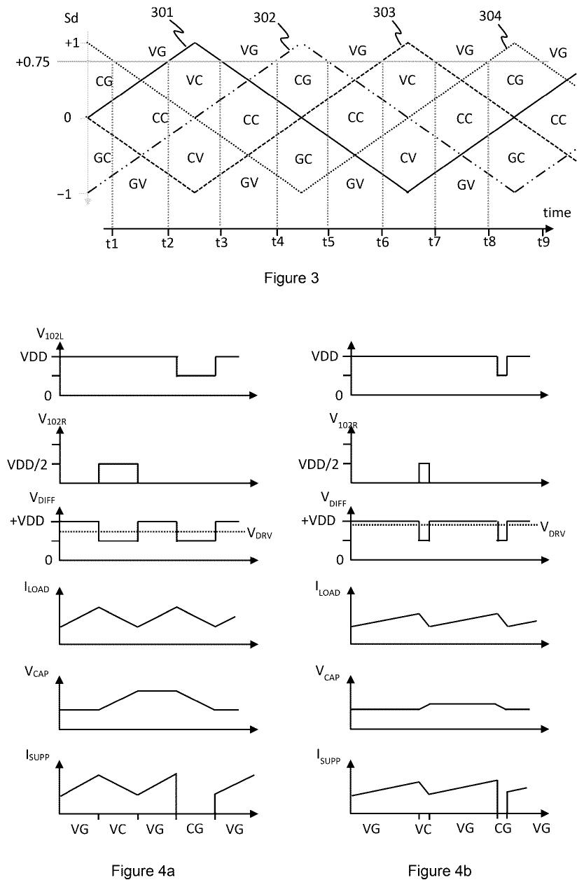

FIG. 3 illustrates one example of a modulation control scheme for the switching driver of FIG. 2;

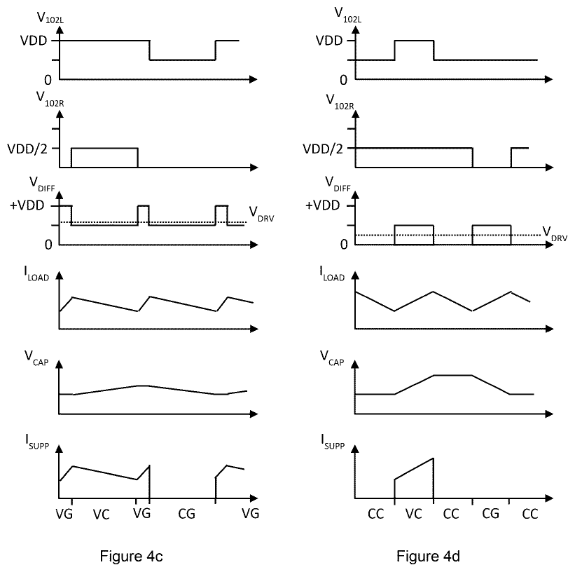

FIGS. 4a through 4d illustrate various waveforms of the switching driver in different states of operation;

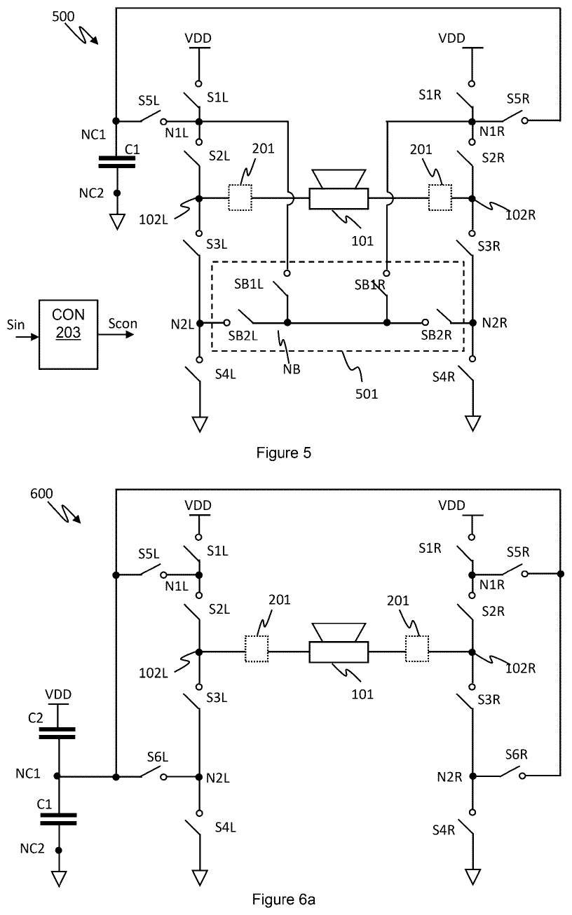

FIG. 5 illustrates an example of a multi-level switching driver according to an embodiment;

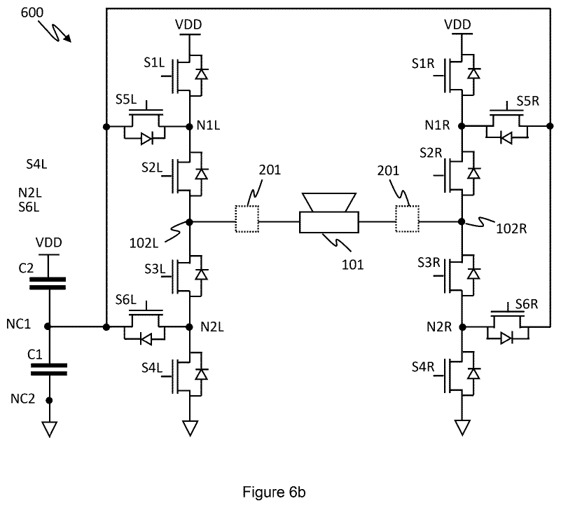

FIGS. 6a and 6b illustrate a further example of a multi-level switching driver according to an embodiment;

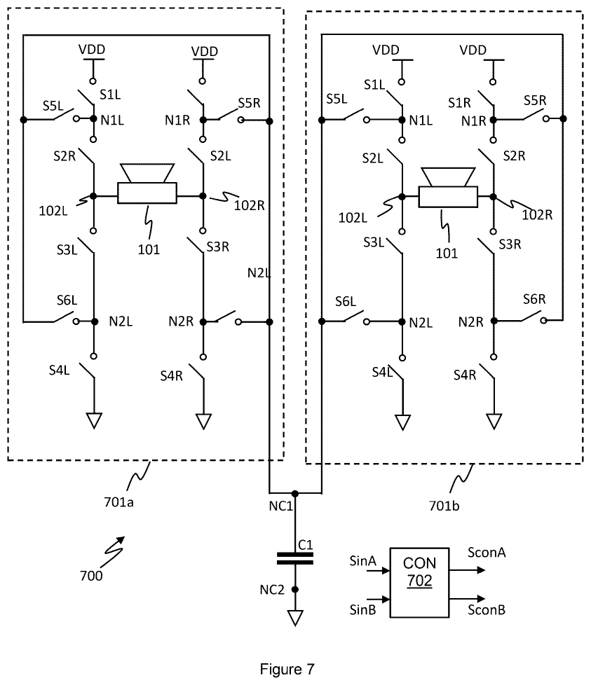

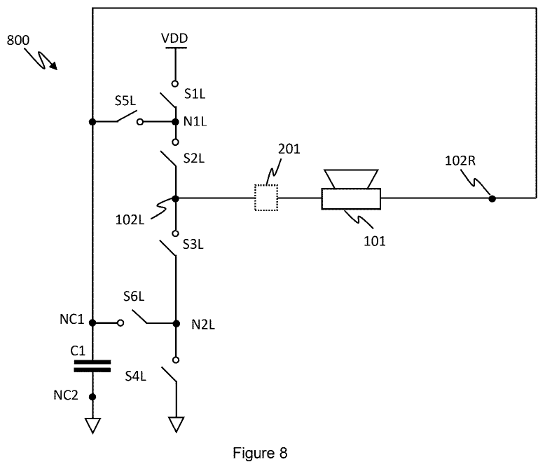

FIG. 7 illustrates a multi-channel system with a common driver capacitance; and

FIG. 8 illustrates an example of a single ended multi-level switching driver.

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Multi-level switching drivers or switched mode amplifiers for driving a transducer have been previously proposed. FIG. 1 illustrates one example of a multi-level switching driver 100 with flying capacitors for driving a load 101, which is based on the known flying capacitor multi-level inverter topology. The switching driver 100 is configured to drive the load 101, which in this example is an audio transducer, in a bridge-tied-load (BTL) configuration, and thus, in use, the load 101 is connected between first and second output nodes 102L and 102R, each of which is modulated, in use, between selected switching voltages with a controlled duty-cycle so as to generate a desired drive signal voltage across the load, on average, over the course of one or more switching cycles.

Switches S1L and S2L are connected in series between a first supply voltage, in this example VDD, and the output node 102L, with a node N1L between the switches. Switches S3L and S4L are connected in series between the output node 102L and a second supply voltage, in this example ground, with a node N2L between the switches. The first and second supply voltages define an input voltage for the switching driver, which in this example is equal to VDD. A capacitor CFL is coupled between nodes N1L and N2 as a first flying capacitor. The other side of the load has an equivalent set of switches S1R to S4R, with the output node being connected between the switches S2R and S3R and a second flying capacitor CFR is connected between nodes N1R and N2R. In use, each of the first and second flying capacitors CFL and CFR, is charged to a voltage which is an intermediate voltage between the first and second supply voltages which, in this example is equal to VDD/2.

The two sets of switches S1L to S4L and S1R to S4R are operable such that a differential voltage of any of +VDD, +VDD/2, zero, −VDD/2 or −VDD can be applied across the load in different switch states. A controller 103 is configured to generate switch control signals Scon for controlling the switches S1L to S4L and S1R to S4R so as to switch between selected states with a controlled duty-cycle, based on an input signal Sin, to generate the desired drive voltage across the load, where the drive voltage is the average voltage over the course of one or more switching cycles.

Whilst a switching driver such as illustrated in FIG. 1 can be usefully used in a range of applications, one complication is the need to balance the charge on the flying capacitors CFL and CFR to maintain the correct voltage on each of the driver capacitors. A standard switching sequence for the switching driver 100 typically alternates between charging one of the flying capacitors while delivering a voltage to the load and then subsequently using a switching configuration that discharges that flying capacitor. To maintain the correct charge balance, and hence the voltages on the flying capacitors, it is generally necessary to measure the voltage of each the flying capacitors and modify the switching sequence as necessary, which can require relatively complex monitoring and control functionality.

It has also been proposed that an intermediate voltage may be generated and regulated by using some specific power supply, for instance U.S. Pat. No. 10,985,717 describes a multi-level class D amplifier in which a multi-level power supply is used to supply separate voltage levels, such as VDD and VDD/2. This can avoid issues with the use of flying capacitors to generate an intermediate voltage but requires a power supply to generate and regulate the intermediate voltage.

At least some embodiments of the present disclosure relate to switching drivers that at least mitigate some of these issues.

FIG. 2 illustrates one example of a switching driver 200, or amplifier, according to an embodiment of this disclosure, in which similar components as those discussed with reference to FIG. 1 are identified with the same reference numerals.

FIG. 2 illustrates that the load 101, which may be a transducer load such as an audio output transducer, is connected in a BTL configuration between first and second output nodes 102L and 102R. In a similar arrangement to the switching driver discussed with reference to FIG. 1, switches S1L and S2L are connected in series between a first supply voltage, in this example VDD, and the output node 102L, with a midpoint node N1L between these switches, and likewise switches S1R and S2R are connected in series between the first supply voltage and the output node 102R with a midpoint node N1R. However, in the example of FIG. 2, there is a single switch S34L connected between the output node 102L and a second supply voltage, in this example ground, and likewise a single switch S34L connected between the output node 102LR and the second supply voltage.

The example of FIG. 2 has a driver capacitor C1 connected in series between first and second capacitor nodes NC1 and NC2 respectively where the first capacitor node NC1 (connected to a first electrode of the driver capacitor C1) can be selectively independently connected to (or disconnected from) each of nodes N1L and N1R by switches S5L and S5R respectively. The second capacitor node NC2 (connected to the second electrode of the driver capacitor C1) is coupled to a defined voltage, which in this case is the second supply voltage, i.e. ground in this example. This defined voltage does not substantially vary in use, i.e. is held at a nominally constant value, and thus the second electrode of the driver capacitor C1 is, in use, effectively tied to this defined voltage, e.g. tied to ground.

In use, the driver capacitor C1 is charged to a desired voltage which may be a fraction, such as a half, of the input voltage defined by the first and second supply voltages, e.g. in the example illustrated the driver capacitor is charged, in use, to a voltage equal to +VDD/2. It should be noted, however, that the voltage of the driver capacitor C1 could be set to some other fraction of the input voltage defined by the first and second supply voltages.

In some implementations, an initial charge on the driver capacitor C1 may be developed, on start-up of the switching driver 200, by arrangement of the driver capacitor C1 as part of a capacitive divider. For instance, an additional capacitor (not illustrated in FIG. 2) could be connected between the supply voltage VDD and node NC1, so that, on start-up, the driver capacitor C1 and additional capacitor are connected in series between VDD and ground with no loading of the node NC1, e.g. with switches S5L and S5R open. In this way the voltage VDD will be divided across the additional capacitor and driver capacitor C1 according to their respective capacitance values, e.g. if the additional capacitor had the same capacitance value of the driver capacitor C1 the voltage would be shared equally and the driver capacitor C1 would be charged to VDD/2. It will be noted that such a capacitive divider arrangement could provide an initial charge for the driver capacitor C1 on start-up, but the voltage of the driver capacitor C1 is subsequently regulated, in use, as will be described below. One skilled in the art will also understand, that there are other ways in which the driver capacitor C1 could be initially charged to the desired voltage on start-up which could be implemented in other embodiments.

Switches S1L to S5L and S1R to S5R form a switch network of the switching driver which is operable such that, in use, each of the output nodes 102L and 102R can be selectively independently connected to the first supply voltage, i.e. VDD, to the voltage of the driver capacitor C1, i.e. to VDD/2 or to the second supply voltage, i.e. to ground. In use, the controller 203 may control the switch network of the switching driver 200 to operate in a sequence of different states so as to generate the desired drive signal for the load 101.

In at least some implementations, there may be an output filter arrangement 201 for applying filtering in the output path to the load. As will be understood by one skilled in the art, for some applications, some filtering in the output path may be important, for instance for relatively high-power applications, e.g. for driving an output power of 10 mW or greater, and/or where the output path between the output nodes of the switching driver and the load 101 may be relatively long, e.g. of the order of tens of centimetres or greater. For example, audio systems in automotive applications and home theatre and the like may typically be required to output relatively high output powers and may have output paths of the order of tens of centimetres to meters between the switching driver and the loudspeaker being driven and, in such applications, EMI may be a particular concern. Filtering of the output path may thus be important. Typically, the output filter may comprise an LC (inductance-capacitance) filter arrangement which is separate to the load 101. FIG. 2 illustrates one example of a basic filter arrangement with a series inductance Lfil in the output path and capacitance Cfil between the output path and a defined reference voltage, such as Ground, on each side of the load.

Other LC filter arrangements may be implemented, however, as would be understood be one skilled in the art, but in general there may be some significant inductance in the output path. Additionally, there may be some capacitance across the load 101. The filter arrangement 201 will generally be configured to provide desired filter characteristics for the relevant application, e.g. for audio applications the filter arrangement 201 may be implemented to provide a cut-off frequency above about 20 KHz. Embodiments of the present disclosure may thus be configured to be able to drive the load via an LC filter arrangement with at least one inductor in the output path. In the full bridge (BTL) case, the filter arrangement will generally be symmetric.

The switching driver 200 of FIG. 2 has various advantages compared to that discussed with reference to FIG. 1. The switching driver 200 can be implemented with just the single driver capacitor C1 for providing the intermediate voltage, i.e. VDD/2, to either of the output terminals 102L or 102R, rather than needing two flying capacitors like the switching driver of FIG. 1. This can have benefits in terms of a smaller circuit area and/or reduced cost.

Also, as mentioned above, the second electrode of the driver capacitor C1 is, via the second capacitor node NC2, tied to a defined voltage, e.g. a reference voltage such as ground. This can improve the efficiency of the switching driver 200. In addition, this can mean the capacitor voltage of the driver capacitor C1 could be monitored in a relatively straightforward manner, if desired. In the example of FIG. 1, for each of the flying capacitors CFL and CFR, the voltage at the first electrode of the flying capacitor depends not only on the voltage of the flying capacitor itself but also on the voltage at the second electrode, which may vary in use as the flying capacitor is switched between the different switch states, which thus complicates the monitoring of the capacitor voltage. For the driver capacitor C1 of FIG. 2, the second electrode is tied to ground (or some other defined, fixed, voltage) via second capacitor node NC2 and thus the voltage of the driver capacitor C1 can be monitored, if desired, by monitoring the voltage at the first capacitor node NC1.

Further, the switching driver 200 of FIG. 2 can be controlled such that the operation of the switching driver 200 to generate the desired drive signal for the load also substantially balances the charge on the driver capacitor C1. That is, the switching of the switching driver 200 between selected switch states, so as to modulate the output voltage across the load and provide the required drive signal, can also provide regulation of the voltage of the driver capacitor C1. As will be described in more detail below, for at least some output voltages, the switching driver 200 is selectively operable in two different states that result in the same differential voltage across the load, one of which involves charging of the driver capacitor C1 by the current in the output load 101 and the other of which involves discharging the driver capacitor C1 to provide the load current. By using instances of both of these states in a switching cycle when appropriate, the charge on the driver capacitor C1 can be substantially balanced whilst operating the switching driver 200 to generate the desired output voltage based on the input signal. Thus, the voltage on the driver capacitor is regulated by the operation of the driver itself and not by the operation of some separate power supply. Thus, the driver apparatus 200 need not have any separate circuitry for separately supplying charge to the driver capacitor C1 in normal operation.

For the purposes of this disclosure, the different states of operation of the switching driver 200 will be identified and labelled using a two-letter code, where the first letter indicates the voltage at output node 102L and the second letter indicates the voltage at output node 102R and where ‘V’ indicates that the relevant output node is connected to the first supply voltage, i.e. VDD, ‘C’ indicates that the relevant output node is connected to the first capacitor node NC1 and hence to the driver capacitor voltage, i.e. VDD/2 and ‘G’ indicates that the relevant output node is connected to the second supply voltage, i.e. ground. For the purposes of this disclosure, a reference to positive voltage across the load, or a positive differential output voltage, shall be taken to mean that the voltage at output node 102L is more positive than the voltage at output node 102R and a reference to a negative output voltage shall mean the opposite. Thus, state VG is a state where the output node 102L is connected to VDD and output node 102R is connected to ground, and the voltage across the load 101 is equal to +VDD, and state CG is a state where the output node 102L is connected to the capacitor voltage of VDD/2 and output node 102R is connected to ground, and the voltage across the load 101 is equal to +VDD/2. A positive load current will likewise be taken to be a load current flowing from the output node 102L to the output node 102R, and a negative current will be taken to be a current in the opposite direction.

The switching driver 200 can operate in a state to VG to generate a positive differential voltage of +VDD across the load, or in the opposite state GV to generate-VDD. In both of these states, the driver capacitor C1 is disconnected from the output terminals 102L and 102R, and hence from the load 101, and thus is neither charged nor discharged by any load current.

To generate a differential voltage of zero across the load, both output nodes 102L and 102R may be connected to the same voltage. A zero differential voltage can be generated in any of states VV, CC or GG, however, it can be advantageous, in some implementations, to use the state CC as the state for zero differential voltage to avoid any discontinuity in common-mode voltage in the different operating states. In this state CC, the first electrode of the driver capacitor C1 is connected to both sides of the load 101 and thus there is no significant charging or discharging of the driver capacitor C1.

To generate a voltage of magnitude VDD/2 across the load with a given polarity, there are two different states that can be used. For instance, +VDD/2 can be output across the load in either the state CG or in the state VC. In the state CG, the output node 102L is connected to the first electrode of the driver capacitor C1 and the output node 102R is connected to ground. Assuming, for ease of explanation, that the load current and voltage are in phase, i.e. a positive voltage across the load leads to a positive load current and vice versa, a positive load current will thus be provided from the driver capacitor C1 and, in this CG state, the driver capacitor C1 will be discharged by the load current. Conversely, in the state VC, the output node 102L is connected to the supply voltage VDD and the output node 102R is connected to the first electrode of the driver capacitor C1. As noted above, the second electrode of the driver capacitor C1 is tied to ground, and thus, in this state VC, the positive load current is sourced from the VDD supply and this load current will charge the driver capacitor C1. Similarly, the two opposite states for generating-VDD/2, i.e. states CV and GC, involve charging and discharging the driver capacitor C1 respectively with a negative load current.

These two different states for generating the same differential output voltage, which involve charging or discharging the driver capacitor respectively, can be used to provide charge balancing of the driver capacitor C1 as part of the modulation scheme of the switching driver apparatus 200, i.e. as part of the normal operation of the switching driver apparatus 200 for generating a desired output voltage based on the input signal Sin. As the relevant two states result in the same differential voltage across the load, the states can be used in a way that results in a substantially matching load current in each case, i.e. the same average current, which means that charge balance can be achieved simply through ensuring equal duration of the charging and discharging states.

For example, to generate a drive signal voltage in the range of +VDD/2 and +VDD, the switching driver 200 may modulate the output voltage across the load between an output voltage of +VDD for part of the switching cycle and an output voltage of +VDD/2 for the rest of the switching cycle. The voltage +VDD can be generated by operating in the state VG. In embodiments of the present disclosure, the proportion of the switching cycle where the switching driver operates to output the voltage +VDD/2 may be divided into equal periods of time spent in the state VC and time spent in the state CG, so that the driver capacitor charges and discharges by an equal amount over the course of the switching cycle. In this way, the charge balance on the driver capacitor C1 can be maintained. The controller 203 may thus be configured to control the switch driver 200 to operate in a sequence of states, such that any instances of operation in state VC are matched by instances of operation of state CG, with the time spent in state VC matched by the time spent in state CG, and likewise any instances of state CV are matched by instances of state GC of equal total duration.

Thus, to generate a positive drive voltage, the switching driver 200 may be cyclically operated in a sequence of states including at least one instance of each of the states VC and CG, where the amount of time spent in state VC during the sequence is equal to the amount of time spent in state CG. For positive drive voltages up to a magnitude of 0.5VDD, the sequence may also include at least one instance of the state CC, i.e. so the sequence comprises instances of each of the states VC, CG and CC. For voltages between +0.5VDD and +VDD, the sequence may include at least one instance of the state VG, i.e. so the sequence comprises instances of each of the states VC, CG and CC.

For negative drive voltages, which may lead to negative load currents, the opposite states may be used, i.e. the sequence of states may include at least one instance of each of the states CV and GC, where the period of time spent in state CV is equal to the period time spent in state GC, and for a drive voltage of magnitude of up to VDD/2 there may be at least one instance of state CC and for drive voltages between −0.5VDD and −VDD the sequence may include at least one instance of the state GV.

There are various ways in which such a modulation scheme may be implemented. In one example, a dual ramp control mechanism may be implemented. For example, four triangle ramp waveforms may be used as different carrier waveforms, where the ramp waveforms have identical slew rates and excursions, but the carrier waveforms have a 90° phase shift from one another, such as illustrated in FIG. 3. FIG. 3 illustrates first, second third and fourth ramp waveforms 301, 302, 303 and 304 that ramp up and down across an operating range, which, for ease of discussion, is illustrated as a normalised range of −1 to +1.

In use, the controller 302 compares a signal Sd, which is based on the input signal and which is indicative of the desired drive voltage within the normalised range (where +1 corresponds to a drive voltage of +VDD and −1 corresponds to a drive voltage of −VDD), to each of the carrier waveforms 301-304 and controls the relevant states of operation of the switching driver apparatus 200 based on the comparison. In an open-loop control scheme, i.e. where the output drive signal is generated based on the input signal Sin without any feedback control, the signal Sd may simply be the input signal Sin, possibly with some gain control applied. However, in a closed-loop implementation, the signal Sd could be based on the input signal Sin processed together with some feedback signal, as will be understood by one skilled in the art.

FIG. 3 illustrates that the different states of operation of the switching driver 200 can be mapped to operating regions based on the relative values of the carrier waveforms. For instance, the state VG may be used when the signal Sd is greater than all four of the carrier waveforms 301 to 304, and similarly the opposite state GV may be used when the signal Sd is lower than all four of the carrier waveforms. If, instead, the signal Sd is lower than just one carrier waveform (and thus greater than the other three), the state may be VC if the carrier waveform that is greater than Sd is one of 301 or 303 (i.e. two of the carriers that have a phase difference of 180° from one another) and the state may be CG when the carrier waveform that is greater than Sd is either of the other carrier waveforms, i.e. 302 or 304. If the signal Sd has a value that is lower than exactly two of the carrier waveforms (whichever two carrier waveforms they are) the relevant state may be CC. If the signal Sd has a value which is higher than just one carrier waveform (so lower than the other three), the state may be CV if the carrier waveform that is lower than Sd is one of 301 or 303 (i.e. two of the carriers that have a phase difference of 180° from one another) and the state may be GC when the carrier waveform that is lower than Sd is one of the other carrier waveforms, i.e. 302 or 304.

As an example of how this may control the switching sequence, FIG. 3 illustrates a line indicating a value of Sd of +0.75, which corresponds to a drive signal voltage of +0.75VDD. The various carrier waveforms 301-304 ramp up and down with a carrier frequency which is significantly higher than the highest frequency components of the required drive signal, e.g. significantly higher than the maximum audio frequency component of an audio drive signal. As such, on the timescale of the cycle period of the carrier waveforms, the value of the signal Sd does not substantially vary.

Starting at time t1, value of Sd is greater than all the carrier waveforms and the switching driver 200 is operating in state VG. At time t2, carrier waveform 301 ramps higher than Sd and the controller 203 causes the switching driver 200 to switch to state VC and stay in this state until the carrier waveform 301 later drops back below the value of Sd at time t3, at which point the switching driver 200 switches back to state VG. At time t4, carrier waveform 302 ramps higher than the value of Sd and the switching driver 200 switches to state CG and remains in this state until time t5, when carrier 302 drops below the value of Sd and the switching driver 200 switches back to the state VG. As carrier waveforms 301 and 302 have the same slew rate and excursion as one another, the period between t2 and t3, which corresponds to the period of operation of state VC, is equal to the period between t4 and t5 which corresponds to the period of operation of state CG. Likewise, the period between t1 and t2 is the same as the period between t3 and t4, which correspond to operation in the state VG. This ensures that the load current at the start of state VC is substantially the same as the load current at the start of state CG and the load current over the duration of the state VC substantially matches the load current over the duration of the state CG, which results in the amount of charging and discharging of the driver capacitor C1 being substantially equal in these two states.

This cycle of states, VG, VC, VG, CG is then repeated in the period between t5, t6, t7, 18 and t9 due to carrier waveforms 303 and 304 ramping above and below the value of Sd and causing the same operation as carriers 301 and 304 respectively. It will be understood that whilst the operation has been described with reference to four carrier waveforms ramping from −1 to +1 and back with a 90° phase difference between each of the carriers, this could equivalently be seen as two positive carriers ramping between 0 and +1 (at twice the frequency) with a 180° phase difference between the two carriers, with the two positive carriers defining when to operate in state VC and when to operate in state CG respectively, and similarly two equivalent negative carriers ramping between 0 and −1 for determining when to operate in the state CV and GC. Thus, for this drive signal voltage of +0.75VDD, the controller 203 may control the switching driver 200 in a switch cycle that has a sequence of states VG, VC, VG, CG, where the time spent in state VC during the sequence is equal to the time spent in state CG, which leads to charge balancing of the driver capacitor C1.

It will be understood, of course, that FIG. 3 represents just one example of a suitable control scheme that the controller 203 may implement to control the operation of the switching driver 200 and other modulation schemes could be implemented in other examples.

FIGS. 4a to 4d illustrate switching waveforms illustrating various voltages and currents of the switching driver 200 for different drive voltages, assuming some inductance in the load path, which could be inductance of the load itself and/or an inductive component in series between output node 102L or 102R and the load. For instance, as noted above, some applications may use inductive filtering in the load path and the inductance could be at least partly due to an inductor Lfil of a filter arrangement 201. Each of these figures illustrates the voltage V_{102L} and V_{102R} at output nodes 102L and 102R respectively over the course of a switching cycle, as well as the resulting differential voltage V_{DIFF}, and also the drive voltage V_{DRV} of the resulting drive signal. The figures also show the load current I_{LOAD}, illustrate how the voltage V_{CAP} of the driver capacitor C1 may vary, and also the current I_{SUPP} which is sourced from the VDD supply. It should be noted that these waveforms are idealised waveforms to illustrate the principles of operation and that the scale of the plots may differ from one another, e.g. the scale for the plot of the capacitor voltage V_{CAP} is much greater than that for other voltages so as to show the voltage ripple on the driver capacitor. These waveforms also assume the voltages and currents are in phase.

FIG. 4a illustrates the switching waveforms for a drive signal voltage V_{DIFF} of +0.75VDD. As described above, this drive voltage could be generated by operating in the sequence of states VG, VC, VG, CC.

During the state VG, the output node 102L is driven to the voltage VDD (by closing switches S1L and S2L) and the output node 102R is driven to ground by closing switch S34R, which results in a voltage V_{DIFF} across the load of +VDD. In this state, the load current I_{LOAD} increases, but the driver capacitor C1 is neither charged nor discharged and thus there is no substantial change in the driver capacitor voltage V_{CAP}. The load current is provided by the input supply and thus there is an increasing supply current I_{SUPP}.

In the state VC, the output node 102L is again connected to the voltage VDD, but the output node 102R is switched to be connected to the driver capacitor C1 (e.g. by opening switch S34R and closing switches S2 and S5R), which results in a voltage V_{DIFF} across the load of +VDD/2. As this is lower than the drive voltage V_{DRV}, the load current I_{LOAD} will start to ramp down, but in the example as illustrated remains positive. This load current I_{LOAD} is sourced from the VDD supply, and thus there is a supply current I_{SUPP}, and this results in charging of the driver capacitor C1, thus increasing the capacitor voltage V_{CAP}.

The switching driver 200 then swaps back to state VG, which again, in this example, causes a ramping in positive load current I_{LOAD} and supply current I_{SUPP}, but no change in capacitor voltage V_{CAP}. The duration of the state VG is such that the load current I_{LOAD} ramps back to its previous peak value before swapping to state CG, which involves output node 102L being connected to the driver capacitor C1 (e.g. by opening switch S1 and closing switch S5L, with switch S2 remaining closed), whilst output node 102R remains connected to ground (via switch S34R). This results in a differential voltage V_{DIFF} of +VDD/2 across the load. Again, as this is lower than the drive voltage V_{DRV} the load current I_{LOAD} ramps down (but remains positive), but, in this state, the positive load current is sourced from the driver capacitor C1 and this discharges the driver capacitor C1, reducing V_{CAP}, and there is no significant supply current I_{SUPP}. The current sourced from the driver capacitor C1 in state CG is equal to the current supplied to the driver capacitor C1 in state VC and thus the capacitor voltage V_{CAP} returns to substantially the same voltage as at the start of the switching sequence.

FIG. 4b illustrates the switching waveforms for a drive signal voltage V_{DIFF} which is greater than +0.75VDD and which is near to the maximum positive drive signal voltage V_{DRV} of +VDD. In this case, the switching driver 200 again operates in a cycle of states VG, VC, CG, VG, but the proportion of the switching cycle spent in the state VG is greater. In this case, the positive load current I_{LOAD} does ramp up in state VG and ramp down in both states VC and GC, but the higher value of V_{DRV} means that there is a reduced rate of ramp up in current in the state VG and an increased rate of ramp down in the states VC and CG. Again, the current supplied to the driver capacitor C1 in state VC is substantially equal to the current drawn from the driver capacitor C1 in the state CG and the voltage V_{CAP} of the driver capacitor C1 is thus maintained over the switching cycle.

FIG. 4c illustrates the switching waveforms for a drive signal voltage V_{DRV} which is lower than +0.75VDD, and which is only slightly greater than +0.5VDD. The switching driver 200 again operates in a cycle of states VG, VC, CG, VG, but the proportion of the switching cycle spent in the state VG is lower than for the example of FIG. 4a.

It will be noted that for each of the examples of FIGS. 4a to 4c, the voltage V_{102L} at output node 102L is at VDD for most of the switching cycle and is modulated to VDD/2 for the duration of the state CG, and the voltage V_{102R} at output node 102R is at ground for most of the switching cycle and is modulated to VDD/2 for the duration of the state VC, which lasts for the same amount of time as state VC. It can therefore be seen that the common-mode component of the voltages at these output nodes is equal to VDD/2.

FIG. 4d, illustrates the switching waveforms for a drive signal voltage V_{DRV} which is substantially equal to +0.25VDD. In this case, as can be seen from FIG. 3, the switching driver 200 may be operated in a sequence of states CC, VC, CC, CG.

In state CC, both output nodes 102L and 102R are connected to the driver capacitor C1 (with switches S2L, S5L, S2R and S5R closed) and so both of these output nodes are driven to VDD/2, so the differential voltage V_{DIFF} across the load is zero. A load current I_{LOAD} (in this example a positive load current) may still flow due to inductance of the load path, but this load current will ramp down and will effectively be recirculated and thus there will be no significant variation in the capacitor voltage V_{CAP}.

The switching driver 200 then switches to state VC, and thus output node 102L is connected to the supply voltage VDD (by opening switch S5L and closing switch S1L, with S2L remaining closed). In this state, the voltage at output node 102L increases to VDD and the differential output voltage V_{DIFF} increase to +VDD/2, which is greater than drive voltage V_{DRV} and results in a ramp up in load current I_{LOAD}, which is sourced from the VDD supply, leading to a supply current I_{SUPP} and resulting in charging of the driver capacitor C1 and an increase in the capacitor voltage V_{CAP}. The switching driver 200 then swaps back to state CC, before switching to state CG, with the output node 102R being connected to ground (by opening switches S2R and S5R and closing switch S34R). This generates a differential voltage V_{DIFF} of +VDD/2 across the load, which is greater than the drive voltage V_{DRV} and results in a ramp up in load current I_{LOAD}, but the load current is sourced from the driver capacitor C1 and thus discharges the driver capacitor C1 with a consequential reduction in capacitor voltage V_{CAP}.

It will be noted that in the example of FIG. 4d, the voltage V_{102L} at output node 102L is at VDD/2 for most of the switching cycle and is modulated to VDD for the duration of the state VC and the voltage V_{102R} at output node 102R is also at VDD/2 for most of the switching cycle and is modulated to ground for the duration of the state CG, which lasts for the same amount of time as state VC. It can therefore be seen that the common-mode component of the voltages at these output nodes is again equal to VDD/2.

A negative drive voltage V_{DRV} would be generated by using the appropriate opposite states, e.g. the states CC, CV, CC and GC for a negative drive voltage V_{DRV} up to a magnitude of 0.5VDD and states GV, CV, GV and GC for a negative drive voltage V_{DRV} with a magnitude in the range of 0.5VDD to VDD. In this case, the waveforms for the capacitor voltage V_{CAP} and supply current I_{SUPP} would be the same as for the relevant opposite state, e.g. state CV would lead to a ramp up in supply current I_{SUPP} drawn from the VDD supply and charging of the driver capacitor C1 resulting in an increase in capacitor voltage V_{CAP}, but the load current I_{LOAD} would flow in the opposite direction and thus be a negative load current ramping up in magnitude.

As noted above, the examples of FIGS. 4a to 4d assume no phase different between the voltages and currents and also illustrate examples where the current direction does not change during the selected sequence of states. It will be understood, however, that the same regulation would apply even if there were a phase difference between the load voltage applied across the load and the load current, e.g. if the load exhibited some resonance, and/or if the load current changed direction during the sequence of states. Operation in the sequence of states as described will lead to at least one period in which the drive capacitor is charged by a positive load current/discharged by a negative load current and which is matched by at least one period in which the drive capacitor is discharged by a positive load current/charged by a negative load current and the positive/negative currents will be the same, on average, during said periods so that the driver capacitor is charged and discharged by the same amount.

It should be clear from the discussion above the charge balance of the driver capacitor C1, and hence the voltage of the driver capacitor C1, can be substantially regulated simply by using the sequence of states discussed with the timings as defined by the control scheme. There is no need to monitor the actual voltage or the driver capacitor or to monitor the actual load current I_{LOAD} in order to provide the regulation described—although in some implementations the capacitor voltage V_{CAP} and/or load current I_{LOAD} may nevertheless be monitored for some additional functionality. The control of the switching driver 200 ensures that if the driver capacitor is used in a state which results in charging of the driver capacitor C1 then there is at least one state that discharges the driver capacitor C1 and the timing of the relevant states provides substantially the desired charge balancing.

If, for any reason, however, equal periods of operation in the charging and discharging states, e.g. the states VC and CG, did not result in correct charge balancing of the driver capacitor, for instance due to unequal load current in these states or leakage, then this could be addressed by a change to the relative durations of these states. For instance, if it is determined that more charge is supplied to the driver capacitor in state VC than is drawn from the capacitor in state CG, or more generally it is determined that the capacitor voltage V_{CAP} is higher than required, the duration of state VC within a switching cycle may be reduced whilst the duration of state CG is correspondingly increased. The overall proportion of the switching cycle spent in states VC and CG is thus not altered, and thus the driver voltage V_{DRV} is not changed, but the amount of charge supplied to the driver capacitor C1 during the state VC will be reduced and the amount of charge drawn from the driver capacitor C1 during the state CG will be increased. Such a change could, for instance, be implemented by the controller effectively changing the phasing of carriers 302 and 304 with respect to carriers 301 and 303.

One issue that can arise, in use, is regulating the charge on the driver capacitor when there is no load current, or only a low level of load current, for example to compensate for leakage from the driver capacitor. For instance, consider the situation where the desired differential drive signal is at or near zero with no significant load current. From FIG. 3 it will be seen that if the signal Sd is at or near zero for an extended period of time, the switching driver 200 may spend all or most of the time in the state CC, with possibly only brief instances of states VC and CG. During such a period, if leakage from the driver capacitor C1 were to occur, this could mean that the voltage of the driver capacitor is not maintained at the correct desired level, e.g. is not maintained at VDD/2. It may therefore be necessary to transfer charge to the driver capacitor to maintain the correct voltage level, but this can be challenging when the load current, over the switching cycle, is at or near zero, as the direction of current flow into and out of the nodes

In embodiments of the present disclosure where there is a significant inductance in the output path, such the filter inductance Lfil, energy can be transferred from the voltage supplies, e.g. from VDD, to the driver capacitor C1 via the inductor without any significant load current. The switching sequence may therefore involve transferring energy from the voltage supplies, e.g. from VDD, to the filter inductor and then subsequently transferring the energy from the filter inductor to the driver capacitor C1. By an appropriate choice of switching states and timings, the average inductor current over the switching cycle may be zero, so that the overall load current is zero, but the net result is that charge is drawn from the relevant supply and charge is supplied to the driver capacitor. Such operation may involve modifying the switching sequence as illustrated in FIG. 3 and may, for instance, involve a brief instant of the state VG to inject charge into the switching driver from the supplies, which can then be transferred to the driver capacitor C1 via the filter inductance Lfil. One skilled in the art would understand there are various switching sequences that could be used to deliver the desired average driver voltage and current over the switching cycle whilst transferring charge to the driver capacitor C1. In at least some embodiments, therefore the controller 203 may be configured, for a signal level below a first threshold (which corresponds to no substantial load current, or only a low load current) to operate in mode of operation which transfers energy to the driver capacitor C1 via the inductor Lfil of the filter arrangement 104.

The discussion above has focused on balancing the charge on the driver capacitor C1, taking account of leakage or other losses, to maintain the voltage of the driver capacitor C1 at the desired voltage level, e.g. at the voltage VDD/2 in the examples discussed above. It will be understood that the voltage on the driver capacitor C1 could be regulated to any desired intermediate voltage between the first and second supply voltages. In addition, it should be understood that the ability to operate in sequence of states that delivers a desired drive voltage, but which varies the net charging or discharging of the driver capacitor C1 over the sequence of states by varying the relative durations of the relevant states could, in some implementations, be used to controllably vary the voltage of the driver capacitor C1 in use.

Thus, the voltage to which the driver capacitor C1 is regulated could, in use, be dynamically varies in use.

In some use cases, however, it may be advantageous to dynamically vary the nominal value of the voltage of the driver capacitor C1 in use. For instance, power efficiency and/or other aspects of performance may, in some cases, be improved by dynamically varying the value of the intermediate voltage of the driver capacitor C1, for instance based on some parameter of operation. In some cases, there can be benefits in varying the value of the intermediate voltage of the driver capacitor C1 based on the level of the input/output signal, e.g. based on signal amplitude in a manner somewhat analogous to envelope tracking in other amplifier topologies. Thus, for example, in some use cases the driver capacitor voltage may be set to VDD, but in other uses cases the driver capacitor voltage may be set to a different value, say reduced to VDD/4. The value of the intermediate voltage of the driver capacitor C1 may, in some implementations, be dynamically controlled based on at least one of: a received input signal; a generated output voltage; a load current provided at the output node or an output power level. The driver capacitor voltage may additionally or alternatively by controlled based on an efficiency measure of the switching driver and/or a switching frequency of the switch states of the switch network. In some cases, the driver capacitor voltage may depend on a system configuration, for example the switching driver may be configured to operate in a relatively low-power, low-performance mode, or in a relatively high-power high-performance mode.

Referring back to FIG. 2, each of the switches S1L to S4L and S1R to S4R could be implemented by any suitable switch arrangement and, in at least some implementations, could be implemented by suitable MOSFET switches.

In the example of FIG. 2, each of switches S34L and S34R should be rated for a voltage stress equal in magnitude to VDD across the switch in the open or off state, as each of the output nodes 102L and 102R can be driven to a voltage equal to VDD whilst the respective switch S34L or S34R is off. However, for switches S1L, S2L, S5L, and equivalently switches S1R, S2R and S5R, the voltage rating of the switches need not be so high, as the maximum voltage stress across these switches in normal operation may be VDD/2. For instance, when output node 102L is connected to the supply voltage VDD, switches S1L and S2L are on, and switch S5L, which is off, is located between node N1L which is at VDD and the first capacitor electrode NC1 at VDD/2, so the voltage stress across switch S5L is equal to VDD/2. When the output node 102L is instead connected to the first capacitor node NC1, switches S2L and S5L are on and the voltage at node N1L is at VDD/2 so the voltage difference across switch S1L is VDD/2. When the output node 102L is connected to ground, both switches S1L and S2L are off. These switches are in series between the supply voltage VDD and the output node 102L at ground and thus divide the voltage across them and switch S5L may be closed to regulate node N2L to the capacitor voltage VDD/2, ensuring that each of switches S1L and S2L only has a voltage of VDD/2 across it. Thus, switches S1, S2 and S5 and equivalently switches S1R, S2R and S5R, may be rated for a voltage stress which is at least VDD/2 but which may be lower than VDD.

It will be noted that the capacitor node NC1 is not directly connected to the output nodes 102L and 102R by switches S5L and S5R respectively, instead switches S5L and S5R connect the capacitor node NC1 to nodes N1L and N1R respectively. This arrangement is beneficial in allowing switches S5L and S5R to be implemented by a single conventional MOSFET device. As will be understood by one skilled in the art, most conventional MOSFETs have a body diode which will conduct if forward biased. Conventional MOSFETs can thus be seen as unidirectional devices in terms of blocking current flow when in the off state. Were switch S5L to connect the capacitor node NC1 to the output node 102L, which can be driven the voltage VDD in the VG or VC states or to ground in the GC or GV state, then the voltage across the switch S5L in the off state could be +VDD/2 or −VVD/2. It would not therefore be possible to implement switch S5L by a single conventional MOSFET with unidirectional current blocking, instead the switch S5L would need to be implemented by two back-to-back MOSFET devices, with increased size and resistive losses, or a MOSFET with bidirectional current blocking capability would be needed, which tends to be more complex and more costly than conventional MOSFETs.

In some applications, it may be advantageous to use switches with a voltage rating lower than VDD for all of the switches of the switching driver, or at least all switches of the switching driver which may pass the load current in use. In some cases, switches with a lower voltage rating may offer improved performance compared to switches with a higher voltage rating. By way of example, it has recently been proposed in automotive applications to use a 48V electrical distribution for electrical systems within the vehicle, instead of the conventional 12V distribution that has previous been used. For a switching driver used in an automotive application, the first and second supply voltages may be 48V and ground, i.e. VDD may be 48V. Transistors rated for 48V can be implemented for switches S34L and S34R of the switching driver 200, but transistors rated for 24V can have some performance benefits. In such an example it may therefore be desirable to implement the switch driver using 24V rated transistors rather than 48V rated transistors.

FIG. 5 illustrates one example of switching driver 500, or amplifier, according to an embodiment which may be implemented using switches which need only be rated for voltage stress of VDD/2. The switching driver 500 includes switches S1L, S2L, S5L, S1R, S2R and

S5R as discussed with reference to the switching driver 200 of FIG. 2, but the single switches S34L and S34R are each replaced with two switches in series. That is, the switching driver 500 comprises switches S3L and S4L between the output node 102L and the second supply voltage, i.e. ground, and switches S3R and S4R between the output node 102L and the second supply voltage, in a similar fashion manner as discussed with reference to FIG. 1.

When the output node 102L is driven to VDD, the voltage VDD is thus applied across the series connection of switches S3L and S4L and each of these switches should thus only experience a fraction of this voltage in terms of voltage stress across the switch. Whilst, ideally, these two switches may divide the voltage stress equally such that the midpoint node N2L between these switches becomes equal to VDD/2, in practice it can be advantageous to actively bias this node to the desired voltage of VDD/2, so that neither switch experiences a voltage stress greater than VDD/2.

The switching driver 500 thus includes a bias network 501 for biasing of nodes of the switching driver 500 so as to maintain a maximum voltage stress of VDD/2 across each of the switches.

As noted above, the switches S5L and S5R can, in use, be closed to bias the voltage at nodes N1L and N1R respectively to the capacitor voltage VDD/2 in any state when the relevant output node 102L or 102R is driven to ground, to ensure that each of switches S1L and S2L or S1R and S2R only experience a maximum voltage stress of VDD/2 across them in the open or off state. The bias network 501 is arranged to also bias the voltage at nodes N2L and N2R to the voltage VDD/2 in any state when the voltage at the relevant output node 102L or 102R is at VDD, so as to ensure that each of switches S3L and S4L or S3R and S4R only experience a maximum voltage stress of VDD/2 across them in the open or off state. Thus, when operating in state VC or VG, the bias network may operate to bias node N2L to the voltage VDD/2 and likewise, when operating in state CV or GV, the bias network may operate to bias node N2R to the voltage VDD/2.

In the example of FIG. 5, the bias network 501 comprises four switches, switches SB1L and SB1R connecting a bias node NB to nodes N1L and N1R respectively and switches SB2L and SB2R connecting the bias node NB to nodes N2L and N2R respectively. In the states VC and VG, switch S5R may be on to drive the voltage at node N1R to VDD/2, either as part of driving the output node 102R to this voltage in the state VC or to manage the voltage stress across switches S1R and S2R in the state VG. In this case, switches S2L and S1R of the bias network 501 may be closed or turned on, which results in the bias node NB and node N2L being biased to the voltage VDD/2. This ensures that the maximum voltage stress across either of switches S3L and S4L is limited to VDD/2.

These switches SB2L and SB1R may also be on during the state CG, as switches S3L and S4L will be off and node N1R will be biased to VDD/2 by switch S5R to manage the voltage stress across switches S1R and S2R in state CG. Thus, switches SB2L and SB1R of the bias network may be closed or on in each of states VG, VC and CG, which are states that may be used only when generating a positive drive voltage.

For the opposite states used to generate a negative drive voltage, i.e. GV, CV and GC, switches S2L and S1R of the bias network 501 may be opened and switches S1L and S1B closed instead. In a similar manner as discussed above, switch S5L may be closed to drive the voltage at node N1L to VDD/2 in all of these states, either as part of driving the output node 102L to VDD/2 or managing the voltage stress across switches S1L and S2L when the output node 102L is at ground, and thus the bias network 501 may connect node N1L to node N2R, so as to bias this node N1L to VDD/2 to manage the voltage stress across switches S3R and S4R.

In state CC, each of switches SB1L to SB2R of the bias network could be open or closed as desired, as in this state each of the output nodes 102L and 102R are driven to VDD/2 and the voltage stress across the switches S1L to S4L and S1R to S4R will be less than VDD/2.

However, in at least some implementations all the switches of the bias network 501 may be closed in the state CC, as this can be beneficial in terms of how the bias network transitions between positive drive voltages and negative drive voltages. For positive drive voltage, switches SB2L and SB1R are closed and switches SB1L and SR2R are open for at least part of the switching sequence, whereas for negative drive voltages, switches SB1L and SB2R are closed and switches SB2L and SR1R are open for at least part of the switching sequence. Any transition between positive and negative driver voltages will involve an instance of a state CC and thus the bias network 501 may transition from only switches SB2L and SB1R being on, to all switches being on, before an instance of a state when switches SB2L and SB1R are turned off, leaving SB1L and SB2R on.

Table 1 below illustrates one example of the different states of operation of the switching driver and which switches are closed or on and which switches are open or off and the resulting voltages at the various node.

TABLE 1

| State | VG | VC | CG | CC | GC | CV | GV |
|---|---|---|---|---|---|---|---|
| S1L | ON | ON | OFF | OFF | OFF | OFF | OFF |
| S2L | ON | ON | ON | ON | OFF | ON | OFF |
| S3L | OFF | OFF | OFF | OFF | ON | OFF | ON |
| S4L | OFF | OFF | OFF | OFF | ON | OFF | ON |
| S5L | OFF | OFF | ON | ON | ON | ON | ON |
| S1R | OFF | OFF | OFF | OFF | OFF | ON | ON |
| S2R | OFF | ON | OFF | ON | ON | ON | ON |
| S3R | ON | OFF | ON | OFF | OFF | OFF | OFF |
| S4R | ON | OFF | ON | OFF | OFF | OFF | OFF |
| S5R | ON | ON | ON | ON | ON | OFF | OFF |
| SB1L | OFF | OFF | OFF | ON | ON | ON | ON |
| SB2L | ON | ON | ON | ON | OFF | OFF | OFF |
| SB1R | ON | ON | ON | ON | OFF | OFF | OFF |
| SB2R | OFF | OFF | OFF | ON | ON | ON | ON |
| N1L | VDD | VDD | VDD/2 | VDD/2 | VDD/2 | VDD/2 | VDD/2 |
| 102L | VDD | VDD | VDD/2 | VDD/2 | GND | VDD/2 | GND |
| N2L | VDD/2 | VDD/2 | VDD/2 | VDD/2 | GND | FLOAT | GND |
| NB | VDD/2 | VDD/2 | VDD/2 | VDD/2 | VDD/2 | VDD/2 | VDD/2 |
| N1R | VDD/2 | VDD/2 | VDD/2 | VDD/2 | VDD/2 | VDD | VDD |
| 102R | GND | VDD/2 | GND | VDD/2 | VDD/2 | VDD | VDD |
| N2R | GND | FLOAT | GND | VDD/2 | VDD/2 | VDD/2 | VDD/2 |

It should be understood that this is just one example of the control of the individual switches to provide the switch states and it would be possible, for at least some states, to vary the control of one or more of the switches, i.e. whether a relevant switch is on or off, without impacting on the voltages at the output nodes or the voltage stress across any switches which are off. For instance, switch S3R could be controlled to be on in the VC state to eliminate the floating voltage, FLOAT, at node N2R and switch S3L could be controlled to be on in the CV state to eliminate the floating voltage at node N2L.

The switching driver 500 with bias network 501 can thus be implemented using switches that need only be rated for a voltage stress of VDD/2 across the switch in the off state. The switches of the bias network 501 itself, i.e. switches SB1L to SB2R, may also have a similar voltage rating, as in all states the bias node NB is biased to VDD/2 and thus the maximum stress across any of the switches of the bias network 501 in the off state is equal to VDD/2.

It should be noted that the bias network serves to provide biasing of nodes of the switching driver 500, so as to manage the voltage stress across some of the switches of the switching driver, but no substantial load current flows via the bias network 501 in use and the load current is thus not delivered via bias network 501. In the bias network 501 of the example of FIG. 5, the bias network 501 operates to connect parts of the switching driver associated with opposite sides of the load 101, i.e. on opposite sides of the bridge of the switching driver 500, but does so for biasing of the switching driver itself, e.g. to manage voltage stress across switches or other components of the switching driver, and not for driving the load. It will of course be understood that the bias network 501 shown in FIG. 5 is just one example and other arrangements of bias network could be implemented.

A switching driver with a bias network for biasing nodes of the switching driver, in particular for connecting parts of a BTL switching driver on opposite sides of the load to provide voltage biasing for the switching driver, represents one novel aspects of the present disclosure. Thus one aspect is switching driver configured to drive a load connected between first and second output nodes in a bridge-tied-load configuration, comprising: first and second switching branches connected to said first and second output nodes respectively, said first and second switching branches being configured to be operable in different switch states to provide different voltages to the relevant output node; and a biasing network connected between the first and second switch branches, the biasing network being configured to switchably connect nodes of the first and second switching branches to controlled voltages to control a voltage stress across switches of the switch branches that are in an off state.

It will be noted that in the example of FIG. 5, switch S5L selectively connects the first capacitor node NC1 to the midpoint node N1L between switches S1L and S2L connected between the output node 102L and the supply voltage VDD, i.e. to the high-side midpoint node, and switch S5R provides a similar connection to the high-side midpoint node N1R on the other side of the load. It will be understood, however, that the switches S5L and S5R could alternatively connect the first capacitor node NC1 to the respective low-side midpoint nodes N2L and N2R. In that case, switch S5L could be closed together with switch S3L to provide the capacitor voltage to the output node 102L via the low-side midpoint node N2L in states CV, CG or CC, and switch S5L could be closed with switches S3L and S3R open to regulate the voltage at the low-side midpoint node N2L in states VG or VC—with the bias network 501 operated to use the voltage at node N2L to also regulate the voltage at the high-side node N1R on the other side of the load in these states. Switch S5R would provide similar operation for the other side of the load.

In some implementations it may be advantageous to be able to selectively connect the first capacitor node NC1 to both the high-side and the low-side midpoint connections on each side of the load, as illustrated in FIG. 6a. FIG. 6a illustrates a switching driver or amplifier similar to that discussed with reference to FIG. 5 in which switches S5L and switches S5R selectively connect the first capacitor node NC1 to the high-side midpoint nodes N1L and N1R respectively, in the same manner as discussed with reference to FIG. 5, but in addition switches S6L and S6R selectively connect the first capacitor node NC1 to the low-side midpoint nodes N2L and N2R respectively. This arrangement avoids the need for the bias network 501 discussed with reference to FIG. 5.

To provide the capacitor voltage to the output node 102L in the states CV, CG or CC. either switch S5L could be closed together with switch S2L or switch S6L could be closed together with switch S3L, however, advantageously both switches S5L and S6L are closed together with switches S2L and S3L to reduce the overall resistance for current flow between the first capacitor node NC1 and the output node 102L. With switches S5L and S2L closed together with switches S6L and S3L, these two switching pathways are connected in parallel which thus reduces the resistance compared to using just one of these switching pathways alone (assuming similar switch on-resistances). In the states VG or VC switch S6L can be closed (with switches S3L and S4L open) to regulate the voltage at the low-side midpoint node N2L and in the states GC or GV switch S5L can be closed (with switches S1L and S2L open) to regulate the voltage at the high-side midpoint node N1L. Switches S5R and S6R on the other side of the load can be operated in a similar fashion. This arrangement thus has the advantages of reduced resistance in some switch states and avoid the need for a separate bias network.

It will be understood that direct switch connection between the first capacitor node and the respectively output nodes 102L and 102R could additionally or alternatively be implemented in some embodiments, either with at least some switches being rated for the full supply voltage VDD or possibly with different arrangements of a bias networks to manage the voltage stress across the switches.

As noted above, for each of the examples of FIGS. 2, 5 and 6a, each of the switches may be implemented by a suitable semiconductor switching device, such as a MOSFET with unidirectional current blocking capability. FIG. 6b illustrates the switching driver of the example of FIG. 6a as may be implemented using conventional MOSFET devices for the switches. Switch S1L is implemented by MOSFET with the body diode arranged to be reverse biased by the voltage VDD, when in the off state and the voltage at node N1L is driven to VDD/2. The body diode of switch S2L is arranged to be reverse biased when in the off state and the voltage at node N1L is driven to VDD/2 and the voltage at node 102L is driven to ground. Likewise, switches S3L and S4L have body diodes which are reverse biased when off and when the voltage at node N2L is driven to VDD/2 and the voltage at node 102L is driven to VDD. Switch S5L has its body diode reverse biased when off and when node N1L is driven to VDD (by switch S1L being on). Switch S6L has its body diode reverse biased when off and when node N2L is driven to ground (by switch S4L being on). The switches S1R to S6R are arranged similarly. This arrangement allows the switching driver to be implemented using convention FET device with a unidirectional current blocking capability.

FIGS. 6a and 6b also illustrates an example in which a second driver capacitor C2 is connected between the first supply voltage VDD and first capacitor node NC1. This arrangement means that the driver capacitors C1 and C2 are effectively connected in series between the first and second supply voltages VDD and ground and collectively maintain the capacitor voltage at the first capacitor node NC1. This can be advantageous in terms of developing an initial charge on each of the driver capacitors C1 and C2 on start-up, as described previously, with the capacitor voltage at the first capacitor node NC1 being regulated in use by operation of the switching driver 600, but it will be understood that embodiments could be implemented with just one of the driver capacitors C1 or C2.

It will be understood that embodiment of switching drivers may thus be implemented with one or more driver capacitors and the reference to a driver capacitor in this disclosure is to a capacitor that is used to store a voltage which is used to provide one of the switching voltages, which may in particular be an intermediate voltage between the first and second supply voltages. Allowing use of just one driver capacitor, that can be used to provide a switching voltage to either side of the load in a BTL configuration, is one advantageous aspect of this disclosure. However, in some applications it may be desirable to use more than one driver capacitor. For instance, it may be desirable in some cases for there to be a driver capacitance which is formed by two or more discreet capacitors arranged in some combination, e.g. a driver capacitance equivalent to the single driver capacitor C1 could effectively be formed by two or more smaller capacitors in parallel and/or driver capacitors may be connected in series as illustrated in FIG. 6. In general, the switching driver may be implemented with a driver capacitance that can be used to provide a switching voltage to either side of the load and the switching driver can be controlled in a manner such that operation of the switching driver to generate the desired drive voltage for the load regulates the voltage on the driver capacitance.

In some examples, the driver capacitor C1 (and/or driver capacitor C2 if present) may be shared between multiple switching drivers, i.e. between multiple amplifiers, for instance between multiple audio amplifiers in a multi-channel audio system. As noted above, the operation of an individual driver or amplifier can be controlled so as to regulate the voltage on the driver capacitor C1 and thus keep it at the correct voltage. This driver capacitor voltage can thus also be used as a switching voltage for one or more other switching drivers, i.e. there may be a common capacitance, connected to a common capacitance node, which is used as a driver capacitor for each of a plurality of switching drivers.

FIG. 7 illustrates an example of an amplifier system 700 comprising multiple switching drivers which share a driver capacitor C1. In the example of FIG. 7, there are two switching drivers, 701a and 701b but it will be understood there could be more in some applications. In the example of FIG. 7 each of the switching drivers 701a and 701b has the structure as discussed with respect to FIG. 6, but it will be understood that any of the embodiments discussed herein could be used as the switching drivers 701a and 702a. Note FIG. 7 does not illustrate a filter arrangement in the output path for a load 101, but it will be understood that a filter, such as an LC filter as discussed with reference to FIG. 2, could be implemented in at least some applications.

Each switching driver 701a and 701b is thus connected to the first capacitor node NC1 and may be operated as described above in a sequence of states which are controlled such that, over the course of the sequence, the total current drawn from the first capacitor node NC1 by that switching driver equals the total current supplied to the first capacitor node and thus operation of the switching driver provides charge balancing for the driver capacitor C1. Each switching driver 701a, 701b may thus be effectively operated in an independent manner based on the relevant input signal to drive its respective transducer.

In some implementations, the different switching drivers may be configured so as to try to minimize the variation in charge of the driver capacitor C1. If both switching drivers 701a and 701b were to be operated in a state that resulted in the respective load current being drawn from the driver capacitor C1 at the same time, there could be a relatively significant decrease in charge of the driver capacitor C1, with an associated droop in the capacitor voltage. Likewise if both switching drivers 701a and 701b supplied current to the driver capacitor C1 at the same time, there could be a relatively significant increase in charge of the driver capacitor C1. However, if one of the switching drivers 701a and 701b was operated in a state that supplied load current to the first capacitor node NC1 at the same time that the other switching driver was sourcing load current from the first capacitor node NC1, the change in charge of the driver capacitor C1 would be a result of any difference in current and thus the variation in charge of the driver capacitor C1 and resultant voltage ripple would be reduced, which may also allow the use of a smaller driver capacitor.

Thus, in at least some applications the operation of the switching drivers 701a and 701b may be arranged such that instances of a state that leads to switching driver 701a drawing load current from the first capacitor node NC1 is likely to occur at the same time as an instance of a state that leads to switching driver 701b providing load current to the first capacitor node NC1. For instance, if the respective input signals SinA and SinB for the switching drivers 701a and 701b were the same as one another, then each instance of a state VC or CV for the switching driver 701a could coincide with an instance of state CG or GC for the switching driver 701a and vice versa. Where the operation in the sequence of states is controlled by comparison with different carrier waveforms, such as discussed with reference to FIG. 3, the same carriers could be used for each switching driver but with an appropriate change in the mapping of the state, or effectively a 180° phase shift could be applied to the carriers for the different switching drivers.

In some applications, a controller 702 could control operation of all of the switching drivers 701a and 701b that share a driver capacitor so as to control the switching drivers to drive their respective transducers based on the respective input signal, e.g. SinA or SinB, and to collectively operate the switching drivers in a selected sequence of states to provide charge balancing of the driver capacitor C1.

The embodiments discussed with reference to FIGS. 2, 5, 6a and 6b show BTL configurations for driving the load, i.e. switching drivers in which the output nodes 102L and 102R on each side of the load can be selectively driven to any of the first supply voltage, i.e. VDD, the intermediate capacitor voltage or the second supply voltage, i.e. ground, such that a differential output voltage can be generated across the load in the range of +VDD to −VDD. The BTL embodiments are advantageous in allowing regulation of the capacitor voltage within a switching cycle of a given amplifier.

Aspects of the present disclosure also relate to single ended drivers.

FIG. 8 illustrates one example of a single-ended switching driver 800 according to an embodiment, in which similar components as described previously are identified by the same reference numerals. In the example of FIG. 8, the output node 102L is connected to VDD via a series connection of switches S1L and S2L and to ground by series connection of switches S3L and S4L, with the high-side and low-side midpoint nodes N1L and N2L between these switches being connected to the first capacitor node NC1 by respective switches S5L and S6L in a similar manner as discussed with reference to FIG. 6. Thus the output node 102L may be selectively connected to any of VDD, ground or the capacitor voltage of the driver capacitor C1. In the example of FIG. 8, however, the output node 102R is tied to the first capacitor node NC1 and thus, in use, is held substantially constant at the intermediate capacitor voltage of the first capacitor terminal NC1.

In use this single-ended switching driver 800 can thus be operated in any of three states, VC, CC or GC so as to develop a voltage across the load in the range of +VDD/2 to −VDD/2 across the load.

For the switching driver 800, in the state VC the driver capacitor C1 will be charged by any positive load current flowing from output node 102L to 102R, but would be discharged by any negative load current, whereas in the state CG, the driver capacitor C1 will be discharged by any negative load current, but would be charged by any positive load current. In this case, the charge on the driver capacitor C1 may not be balanced over the course of an individual switching cycle, as discussed above, but may be regulated on the basis of the signal itself, e.g. over the course of a cycle of the signal. In some cases this may involve modifying the switching cycle, i.e. modifying the signal, to try to ensure an average current of zero over a certain time period. The driver capacitor C1 may therefore be sized appropriately so as to be able to provide the expected amount of charge without undue voltage droop over the relevant time frame.

Additionally or alternatively two or more single-ended amplifiers, such as illustrated in FIG. 8 could be arranged with a common driver capacitance, such as discussed with respect to FIG. 7, and the operation of the two or more single-ended drivers controlled so as to provide voltage regulation of the driver capacitance. In particular, two amplifiers could be arranged such that the driver capacitor is connected such that a positive voltage and positive load current for one amplifier leads to charging of the driver capacitor C1 whereas a positive voltage and positive load current for the other amplifier leads to discharging of the driver capacitor C1. In this way common drive signals for the two amplifiers would lead to charging and discharging of the driver capacitor C1, which can aid in voltage regulation of the driver capacitance.

The examples above have been described in the context of a switching driving which receive first and second voltages as a positive supply voltage and ground, but it will be understood that embodiments may be implemented with split-rail supplies, for instance with positive and negative supply voltages. The supply voltage, as used herein, refers to a voltage supply which is provided to the switching driver circuit. In some cases, there may be some upstream circuitry for processing a received voltage, e.g. a batter voltage or the like, to provide the supply voltage VDD for the switching driver, e.g. to apply some regulation and/level shifting.

The examples above have been discussed primarily in the context of driving an audio transducer, such as a loudspeaker, and embodiment may be implemented as audio switching drivers, i.e. as audio amplifiers. However, embodiments may be used to drive other types of transducers and are applicable to driving any load with a drive signal based on an input signal.

Embodiments may be implemented as an integrated circuit. Embodiments may be implemented in a host device, which may be a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle. There is further provided a host device incorporating the above-described embodiments.

The skilled person will recognise that some aspects of the above-described apparatus and methods, for instance processing of the various signals, may be embodied as processor control code, for example on a non-volatile carrier medium such as a disk, CD- or DVD-ROM, programmed memory such as read only memory (Firmware), or on a data carrier such as an optical or electrical signal carrier. For some applications, embodiments may be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A switching driver circuit for driving a load comprising:
first and second output nodes for outputting a differential drive signal for driving the load via a filter arrangement comprising a series inductance;
first and second supply nodes configured to receive first and second supply voltages respectively;
an intermediate voltage node configured to receive an intermediate voltage provided by a driver capacitance, the intermediate voltage being at a voltage level between the first and second supply voltages;
a driver switch network configured such that each of the first and second output nodes can be selectively connected to a respective selected one of each of the first supply node, the second supply node and the intermediate voltage node;
a controller configured to control the driver switch network to operate in a sequence of said switch states to generate said differential drive signal based on an input signal;
wherein the controller is configured such that operation of driver switch network in said sequence of switch states to generate said differential drive signal regulates the intermediate voltage provided by said driver capacitance.

2. The switching driver circuit of claim 1 wherein the intermediate voltage provided by said driver capacitance is equal to a voltage which is half of an input voltage defined by the first and second supply voltages.

3. The switching driver circuit of claim 1 wherein the intermediate voltage provided by said driver capacitance is equal to a voltage which is a first fraction of an input voltage defined by the first and second supply voltages, wherein the first fraction is not a half.

4. The switching driver circuit of claim 1 wherein the controller is configured to regulate said intermediate voltage of said driver capacitance so as to dynamically vary a value of the intermediate voltage based on at least one operating parameter of the switching driver circuit.

5. The switching driver circuit of claim 4 wherein said operating parameter comprises at least one of: a level of the input signal; a generated output voltage; a load current; an output power level; an operating mode of the switching driver circuit.

6. The switching driver circuit of claim 1 wherein the filter arrangement further comprises a shunt capacitance.

7. The switching driver circuit of claim 1 wherein, for a level of input signal below a first threshold, the controller is configured to operating a mode of operation in which operation of driver switch network in the sequence of switch states is configured to transfer energy derived from at least one of the first and second supply voltages to the driver capacitance via the inductor of the filter arrangement.

8. The switching driver circuit of claim 1 wherein the driver switch network comprises, for each of the first and second output nodes:
a first set of switches for selectively connecting the relevant one of the first or second output nodes to the first supply node or the intermediate voltage node, and
a second set of switches for selectively connecting the relevant one of the first or second output nodes to the second supply node; wherein
each of the first set of switches comprises a first switch coupled between the relevant one of the first or second output nodes and a respective first common node, a second switch coupled between the respective first common node and the first supply voltage node and a third switch coupled between the respective first common node and the intermediate voltage node.

9. The switching driver circuit of claim 8 wherein each second set of switches comprises one or more switches connected in series between the relevant one of the first or second output nodes and the second supply node.

10. The switching driver circuit of claim 8 wherein each second set of switches is also for selectively connecting the relevant one of the first or second output nodes to the intermediate voltage node and wherein each second set of switches comprises a fourth switch coupled between the relevant one of the first or second output nodes and a respective second common node, a fifth switch coupled between the respective second common node and the second supply voltage node and a third switch coupled between the respective second common node and the intermediate voltage node.

11. The switching driver circuit of claim 10 wherein, in at least one mode of operation, the controller is configured to turn on each of the first, second, fourth and fifth switches of the first and second sets of switches for one of the first or second output nodes to connect that one of the first or second output nodes to the intermediate voltage node.

12. The switching driver circuit of claim 1 wherein the driver switch network is implemented by MOSFET switches with a unidirectional current blocking capability.

13. The switching driver circuit of claim 1 wherein the input signal is an audio signal.

14. The switching driver circuit of claim 1 wherein the load is an audio output transducer.

15. A driver apparatus comprising the switching driver circuit of claim 1, the filter arrangement and the load.

16. A switching driver circuit for driving a load comprising:
a first output node for outputting an output signal to a filter arrangement comprising a series inductance;
first and second supply nodes configured to receive first and second supply voltages respectively;
an intermediate voltage node configured to receive an intermediate voltage provided by a driver capacitance which is at a voltage level which is between the first and second supply voltages;
a driver switch network configured such that the first output node can be selectively connected to a selected one of each of the first supply node, the second supply node and the intermediate voltage node;
a controller configured to control the driver switch network to operate in a sequence of said switch states based on an input signal such that output signal, after filtering by said filter arrangement, corresponds to the input signal;
wherein the controller is configured such that operation of driver switch network in said sequence of switch states to generate said differential drive signal regulates the intermediate voltage provided by said driver capacitance.

17. The switching driver circuit of claim 16 wherein the filter arrangement further comprises a shunt capacitance.

18. The switching driver circuit of claim 17 wherein, for a level of input signal below a first threshold, the controller is configured to operating a mode of operation in which operation of driver switch network in the sequence of switch states is configured to transfer energy derived from at least one of the first and second supply voltages to the driver capacitance via the inductor of the filter arrangement.

19. A switching driver circuit for driving a load comprising:
first and second output nodes for outputting a differential drive signal for driving the load;
first and second supply nodes configured to receive first and second supply voltages respectively;
an intermediate voltage node configured to receive an intermediate voltage provided by a driver capacitance, the intermediate voltage being at a voltage level between the first and second supply voltages;
a driver switch network configured such that each of the first and second output nodes can be selectively connected to a respective selected one of each of the first supply node, the second supply node and the intermediate voltage node;
a controller configured to control the driver switch network to operate in a sequence of said switch states to generate said differential drive signal based on an input signal;
wherein the driver switch network comprises, for each of the first and second output nodes:
a first set of switches for selectively connecting the relevant one of the first or second output nodes to the first supply node or the intermediate voltage node, and
a second set of switches for selectively connecting the relevant one of the first or second output nodes to the second supply node; wherein
each of the first set of switches comprises a first switch coupled between the relevant one of the first or second output nodes and a respective first common node, a second switch coupled between the respective first common node and the first supply voltage node and a third switch coupled between the respective first common node and the intermediate voltage node.
